(19) United States
(12) Patent Application Publication
(10) Pub. No.: US 2003/0043560 A1
(43) Pub. Date: Mar. 6, 2003

(54) Printed circuit board having a microelectronic semiconductor device mount area for trace routing therethrough

(76) Inventors: Robert Roy Clarkson, Garland, TX (US); Glen Robert Harding, Garland, TX (US)

Correspondence Address: GRAY, CARY, WARE & FREIDENRICH LLP, 1221 SOUTH MOPAC EXPRESSWAY, SUITE 400, AUSTIN, TX, 78746-6875, US

(21) Appl. No.: 09/882,722

(22) Filed: Jun. 15, 2001

(51) Int. Cl. H05K 7/06

(52) U.S. Cl. 361/782; 361/777; 174/262; 174/261; 174/250

(57) ABSTRACT

An optimal microelectronic semiconductor device mount area on a printed circuit board is provided. A novel mount area includes a plurality of collinear arrangements of attach pads and collinear arrangements of vias so that, at a minimum, at least one signal trace may be routed directly through the mount area. Additionally, capacitors may be coupled directly within the mount area on a bottom surface of the printed circuit board. The mount area includes a plurality of collinear arrangements of attach pads and a plurality of collinear arrangements of vias. Each of the collinear arrangements of attach pads are preferably separated from the nearest adjacent collinear arrangements of attach pads by an equivalent distance. A plurality of collinear arrangements of vias are separated from adjacent collinear arrangements of vias by a first distance. At least two mutually adjacent collinear arrangements of vias define a trace routing channel through the mount area.

### TECHNICAL FIELD OF THE INVENTION

The present invention relates to assembly methods of printed circuit boards and to printed circuit boards obtained thereby and, in particular, to optimal via and microelectronic semiconductor device attach pad configurations providing improved signal trace routings on a printed circuit board.

### BACKGROUND OF THE INVENTION

Printed Circuit Board (PCB) manufacturers are under continual pressure to provide reduction in board sizes. Production of reduced size PCBs is often complicated by the concurrent market demand for increasingly sophisticated electronic devices and the corresponding requisite density of circuitry and semiconductor devices for providing increased levels of functionality for a PCB.

While the seemingly conflicting demands for reduced PCB size and increased PCB capabilities are partially addressed by improvements in miniaturization made by the semiconductor industry, PCB manufacturers nevertheless find demand for reduced PCB size and consequential increases in PCB component densities. Furthermore, improvements in semiconductor fabrication techniques resulting in improved miniaturization often complicate PCB manufacture. As I/O signal densities of semiconductor devices increase, it becomes more technologically challenging to accommodate these devices and the associated signal traces on smaller PCBs that are required by today's electronic devices.

Numerous integrated circuit packaging schemes have been developed over the years for addressing I/O and package sizing requirements. Dual in-line packages (DIP) are still common although DIPs are inefficient from a miniaturization standpoint. A DIP package typically features a ceramic body having leads along two opposing edges. Generally, DIPs are utilized for low complexity devices where minimization of the surface mount area is not critical.

Pin grid arrays (PGAs) were developed for addressing rising I/O requirements of semiconductor chips and are generally implemented in larger chips with more leads than found in DIPs. Pin grid arrays feature connections, in the form of pins, covering the entire bottom surface area of the chip as opposed to peripheral leads found on most chips.

Ball grid arrays (BGAs) are generally configured much like a PGA. Rather than pins, BGAs feature solder balls on the package bottom for mounting with a PCB. By utilizing the entire chip surface for electrical connections, the chip package surface area, as well as the weight, are significantly reduced compared to chips featuring only chip peripheral leads.

A consequence of increased I/O signal densities associated with chips such as BGAs is an increase of trace population and trace density on the PCB. In order to minimize the PCB profile, or surface area, more narrow trace lines or additional PCB layers are often required. The ability to minimize trace line widths is limited. Adding additional PCB layers is, therefore, often the only practical solution. Because the number of layers of a PCB generally impacts the PCB manufacturing cost more than gains from reducing the surface area, it is clearly advantageous to minimize the number of PCB layers by effectively utilizing the surface area of a PCB by providing efficient, dense trace routing.

One of the more common and frustrating problems encountered when designing trace routings for PCBs is finding routing channels that pass through BGA mount areas. Redesign of the trace routings is often required. Barring available PCB area, the addition of PCB layers may be required. When board space is available on another existing PCB layer, additional routing vias may be added to the PCB to utilize this space. However, the routing vias themselves consume valuable routing space.

Therefore, it may be seen from the foregoing that a solution for routing trace lines on a PCB densely populated with chips such as BGAs and PGAs while minimizing the need for routing vias is desired.

### SUMMARY OF THE INVENTION

In an embodiment of the present invention, an optimal microelectronic semiconductor device mount area on a printed circuit board is provided. The optimal mount area includes a plurality of collinear arrangements of attach pads and collinear arrangements of vias so that, at a minimum, at least one signal trace may be routed directly through the mount area. Additionally, capacitors may be coupled directly within the mount area on a bottom surface of the printed circuit board. Each of the collinear arrangements of attach pads are preferably separated from the nearest adjacent collinear arrangements of attach pads by an equivalent distance. A plurality of collinear arrangements of vias are separated from adjacent collinear arrangements of vias by a first distance. At least two mutually adjacent collinear arrangements of vias have a separating distance approximately equal to two times the first distance, thereby defining a trace routing channel through the mount area.

### BRIEF DESCRIPTION OF THE DRAWINGS

A more complete understanding of the method and apparatus of the present invention may be had by reference to the following detailed description when taken in conjunction with the accompanying drawings wherein:

FIGS. 1A and 1B are, respectively, an upper and lower view of a conventional attach pad and via configuration associated with a BGA mount area of a printed circuit board;

FIGS. 2A and 2B are, respectively, an upper and lower view of an attach pad and via configuration associated with a BGA mount area of a printed circuit board according to an embodiment of the present invention;

FIGS. 3A and 3B are, respectively, an upper and lower view of an attach pad and via configuration associated with a BGA mount area of a printed circuit board according to an alternative embodiment of the present invention;

FIGS. 4A and 4B are, respectively, an upper and lower view of a printed circuit board incorporating a BGA mount area according to the teachings of the present invention; and

FIG. 5 is an upper view of a printed circuit board including a plurality of BGA mount areas according to the teachings of the present invention.

### DETAILED DESCRIPTION OF THE INVENTION

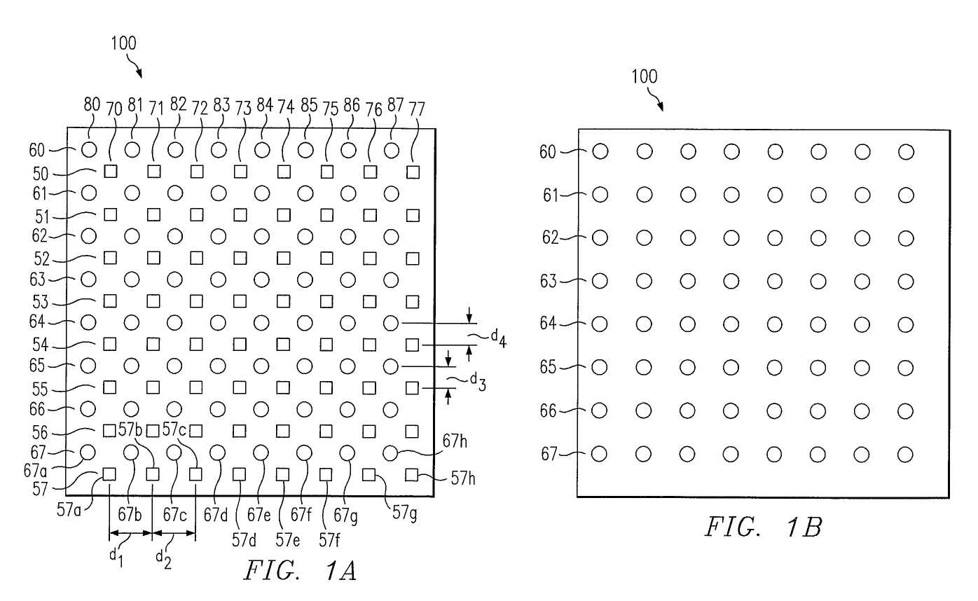

The preferred embodiment of the present invention and its advantages are best understood by referring to FIGS. 1-5 of the drawings, like numerals being used for like and corresponding parts of the various drawings.

As is known in the art, vias provide electrical connections from one layer of a printed circuit board to another. Vias can be created by a number of processes including mechanical drilling, laser drilling and dry etching techniques. A via is simply a hole through one or more layers of the printed circuit board and is typically plated to assure good electrical conduction between layers. Vias may pass through only a single layer of the PCB, for example in a two-layered board, or they may pass through multiple layers when signal routing is required between non-adjacent PCB layers. Other vias may pass completely through a PCB, for example to provide routing for adjacent source voltage pads or ground pads, and are commonly referred to as clearance vias. By using clearance vias, a single source voltage pad can be used to provide a voltage source for all layers of a multi-layered PCB.

Routing vias are used to provide signaling between PCB elements when providing a direct signal trace is either not possible or is logistically unattractive. The use of routing vias typically results from trace densities so large that accommodation of additional traces is not possible. Areas proximate high input/output semiconductor chips typically have large trace densities. Consequently, these areas often require routing vias.

Ball grid arrays, and similar microelectronic semiconductor devices, often require a substantial number of vias due to the large, local trace density associated with the BGA mounting area of the PCB. While efforts continue to accommodate larger trace densities by shrinking trace dimensions, there is inarguably a limit to miniaturization of the trace itself. Furthermore, semiconductor chip miniaturization continues to outpace advances in reductions to trace dimensions, a scenario further complicating the task of PCB manufacturers.

An exemplary attach pad and via configuration associated with a BGA mount area 100 of a PCB is illustrated in FIGS. 1A and 1B. This configuration includes rows 50-57 of attach pads, for example attach pads 57a-57h of attach pad row 57, adjacent to rows 60-67 of offset vias, for example vias 67a-67h of via row 67, forming respective attach pad and via columns. The mount area 100 is thereby formed of a plurality of collinear arrangements of attach pads and a plurality of collinear arrangements of vias, each collinear arrangement respetively including a plurality of attach pads and vias. Each collinear arrangement of attach pads has adjacent thereto at least one collinear arrangement of a plurality of vias. Thus, in this typical arrangement, the PCB is designed with a via placed on the board for each attach pad of the BGA. The channel diameter is typically minimized to provide the lowest BGA profile, or footprint, attainable. Generally, each attach pad of a collinear arrangement, for example each of the attach pads of row 57, are equally spaced from adjacent attach pads in the same row, that is the distance d₁ is typically equivalent to the distance d₂. Furthermore, each row of attach pads generally share a common attach pad separating distance d₁. Each collinear arrangement of vias are generally spaced an equivalent distance from adjacent collinear arrangements of attach pads. For example, via row 67 is separated from attach pad row 57 by a distance d₃. The distance d₄ separating via row 66 from attach pad row 56 is typically equivalent to d₃.

One of the more frustrating problems encountered during PCB design is the placement of a PCB mount area 100 in the path of a needed signal trace. For example, on a board having already limited space for laying signal traces, the requirement for mounting a semiconductor chip may obstruct desired trace routes. The physical placement of the chip on the PCB may often be critical. Moving a chip away from an already trace dense area proximate a data bus, for example, may cause undesirable system performance degradations. It is the PCB designer's task to find alternative trace routes or, when no alternative routes are available, to drop a routing via on the PCB. In the latter event, if the trace route terminates on the same PCB layer on which it originates, a second routing via is then required to return the trace to the originating layer. On PCBs having large trace populations and large numbers of chips mounted on the PCB, routing space becomes even more critical. It is clearly advantageous to minimize the number of routing vias because each routing via reduces the available routing area by the dimensions of the via.

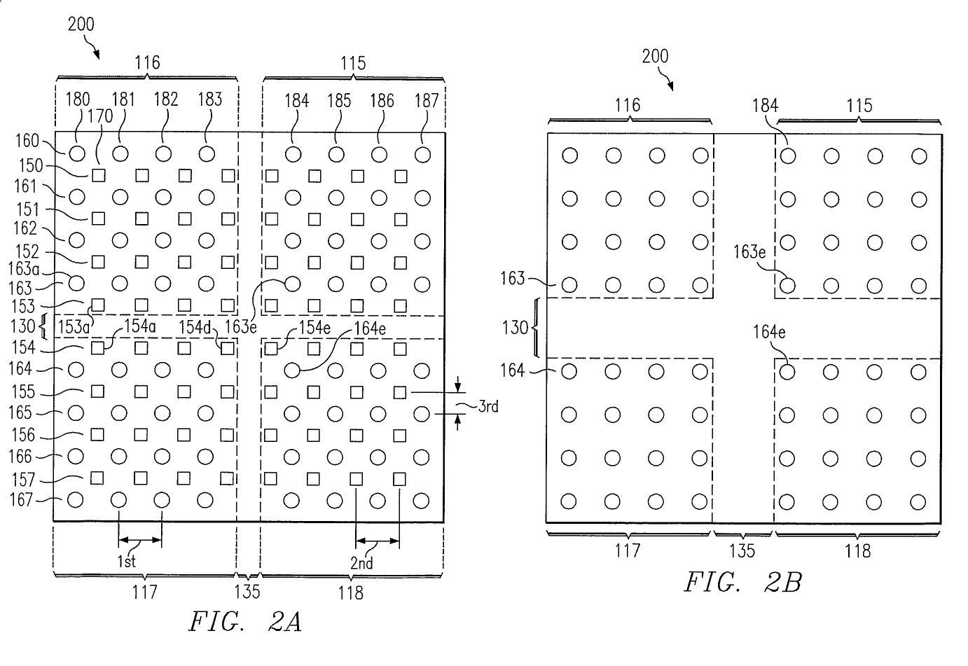

The present invention provides a technique for minimizing, or even eliminating in some cases, the need for routing vias used for averting BGA mount areas during trace routing. In FIGS. 2A and 2B, there are respectively illustrated a top and bottom view of a BGA mount area 200 having a novel attach pad and via configuration according to an embodiment of the present invention. Rows 150-157 of attach pads have offset rows of vias 160-167 respectively adjacent thereto. By offsetting rows of vias adjacent to each row of attach pads, each attach pad, for example attach pad 153a, has a via, for example via 163a, associated therewith for routing signals from each of the attach pads included in the BGA mount area 200.

As mentioned hereinabove, the high trace densities associated with BGA mount area 200, and mount areas for other similar high I/O signal devices, generally preclude the possibility for routing a trace through the mount area. This results from miniaturization trends in semiconductor device manufacturing techniques to shrink the device packages as much as possible. The resulting compact packages have leads densely packed together. The channel width between leads is generally large enough to accommodate a single trace—typically used by the trace from the attach pad to the associated via.

Heretofore, a routing via, through which a signal trace is passed to another PCB layer, is typically placed in close proximity to the mount area 200 when a route to a desired termination point is obstructed by the BGA mount area 200. The present invention overcomes the need for placement of routing vias in these circumstances. As depicted in FIG. 2A, the mount area 200 is divided into multiple quadrants having channels between any two adjacent quadrants. In this illustrative example, four via and attach pad quadrants 115-118 (illustratively encompassed with dashed lines) are formed by a novel arrangement of the vias in relation to the associated attach pads. Two perpendicularly oriented channels, one generally horizontal channel 130 and one generally vertical channel 135, result from the formation of the via and attach pad quadrants 115-118. In the present example, the quadrants are defined, in effect, by removing the innermost column and row of vias from the traditional attach pad and via configuration and respectively replacing them along the most peripheral row and column of attach pads. Constructed in this manner, channels 130 and 135 can be used for trace routing directly through the BGA mount area.

Notably, the attach pad rows 150-157 as oriented in the mount area 200 of the present invention (FIG. 2A) are identically arranged as the attach pad rows 50-57 (FIG. 1A) of the prior art mount area 100. Therefore, no modification to the semiconductor ball-grid arrays is required to make use of the present invention.

Two distinct advantages are provided by the present invention. With reference again to FIG. 2A, channels 130 and 135 may be used for routing traces on the upper side of the PCB directly through the mount area 200, thereby avoiding the use of a routing via when a BGA, for example, obstructs a desired trace route. Furthermore, on the underside of the PCB the widths of the channels 130 and 135 are larger (as can be seen in FIG. 2B) than the channel widths on the upper side. This results from the underside channel widths being defined by the distance between vias, whereas on the upperside the channel widths are defined by the distance between adjacent attach pads. Because the channel is created by eliminating an intermediate collinear arrangement of vias, for example a row or column of vias, the channel width on the upperside of the PCB will be equivalent to the distance between two adjacent collinear arrangements of attach pads whereas on the bottom side of the PCB, the channel width will be equal to approximately twice the distance between two adjacent via rows (or columns) in conventional PCBs. More specifically, the width of channel 130 on the upperside is equal to the distance between any two attach pads adjacent to channel 130 and located in a common attach pad column, for example attach pads 153a and 154a respectively contained within quadrants 116 and 117 and attach pad column 170. The width of channel 135 on the upperside of the PCB is likewise determined from the distance between any two attach pads adjacent to channel 135 and located in a common attach pad row, for example attach pads 154d and 154e respectively contained within quadrants 117 and 118 and attach pad row 154. It is understood that microelectronic semiconductor devices generally are manufactured with uniform lead spacings and channels 130 and 135 would, consequently, have equivalent widths. However, the present invention would be equally applicable for designing mount areas for non-uniform arrays of chip leads.

Because the attach pads only appear on one surface of the PCB, the widths of the channels may be greater on the PCB surface on which the vias terminate. As illustrated in FIG. 2B, the widths of channels 130 and 135 are defined by the spacing of vias adjacent to the respective channels and located in quadrants respectively adjacent to the channel. For example, the width of channel 130 on the underside of the PCB is equal to the distance between vias 163e and 164e respectively contained within quadrants 115 and 118 and attach pad column 184. The width of channel 135 is similarly obtained and will be equivalent to the width of channel 130 if the mount area 200 is designed for a typical semiconductor device having a uniform lead configuration. While the present illustrative example has shown a mount area 200 designed for an 8×8 lead array semiconductor device, it should be clear that the present invention is equally applicable for PCB mount areas designed to accommodate semiconductor devices having more or less leads. Many BGAs today have hundreds of I/O leads. The present example describes an 8×8 array for simplification of discussion only.

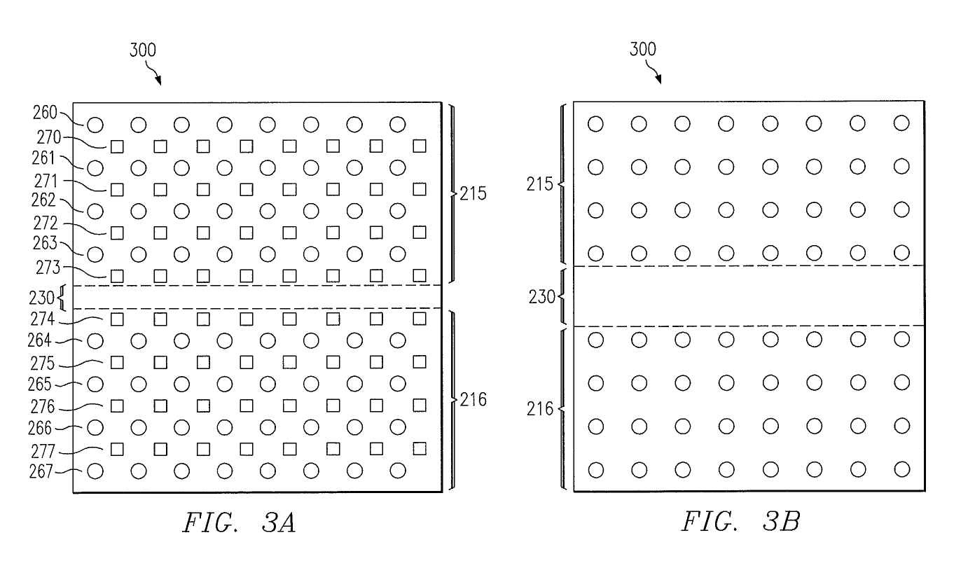

Numerous arrangements of the attach pad and via configuration as taught by the present invention are possible. In FIGS. 3A and 3B, there are respectively illustrated an upper and lower view of a PCB mount area 300 for mounting a BGA and incorporating the teachings of the present invention. The mount area 300 is divided into two quadrants 215 and 216 (illustratively encompassed with dashed lines) of attach pads and associated vias with a single channel therebetween. The embodiment illustrated is designed to accommodate a semiconductor chip having an 8×8 array of leads. Accordingly, the mount area 300 would be suitable for mounting a chip with an equivalent lead configuration as the previously discussed embodiment, with reference to FIG. 2, and the prior art mount area configuration, as discussed with reference to FIG. 1.

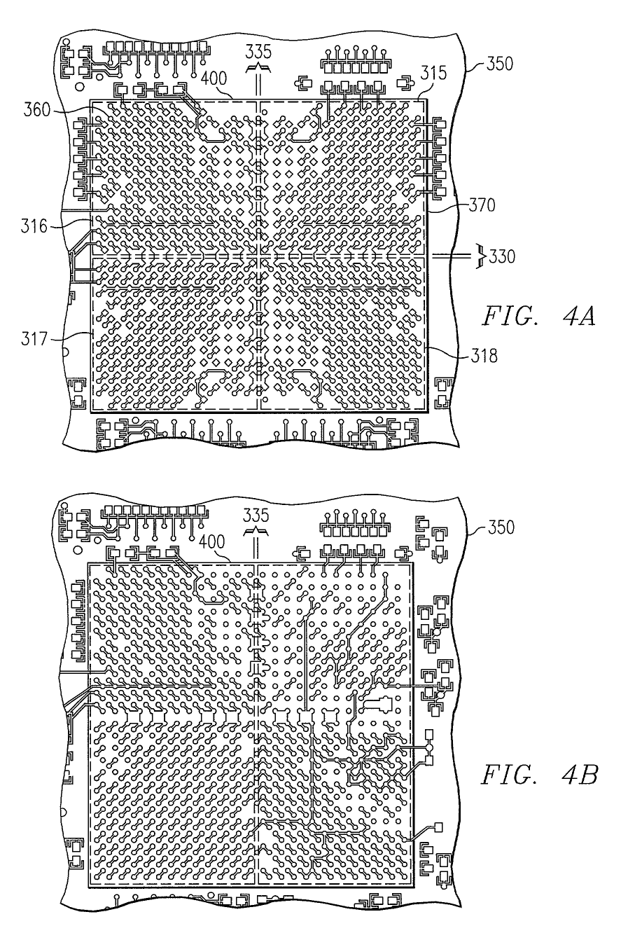

With reference now to FIGS. 4A and 4B, there are respectively illustrated top and bottom views of a printed circuit board 350 having a semiconductor device mount area 400 incorporating the teachings of the present invention. Semiconductor device mount area 400 includes a novel arrangement of rows of attach pads, for example attach pad row 360, and rows of vias, for example via row 370 (and consequently columns of both attach pads and vias). Two channels, one horizontally oriented channel 330 and one vertically oriented channel 335, result from the formation of the via and attach pad quadrants 316 and 317. In the present example, the quadrants are defined, in effect, by omitting an intermediate row and column of vias from a traditional attach pad and via configuration and respectively replacing them along the peripheral row and column of attach pads. Channels 330 and 335 are thereby formed at the respective positions where the via row and column were omitted. These channels can then be used for routing a trace, or multiple traces, directly through the semiconductor mount area 400. Furthermore, on the bottom side of the PCB 350 (FIG. 4B), the channel 330 and 335 dimensions are large enough to accommodate mounting capacitors directly therein. Ground and power vias can advantageously be located adjacent to channels 330 and 335. Decoupling capacitors can then be mounted directly in the channels on the bottom side of the PCB 350 in close proximity to the ground and power vias. Consequently, power decoupling can be performed directly at the component pins.

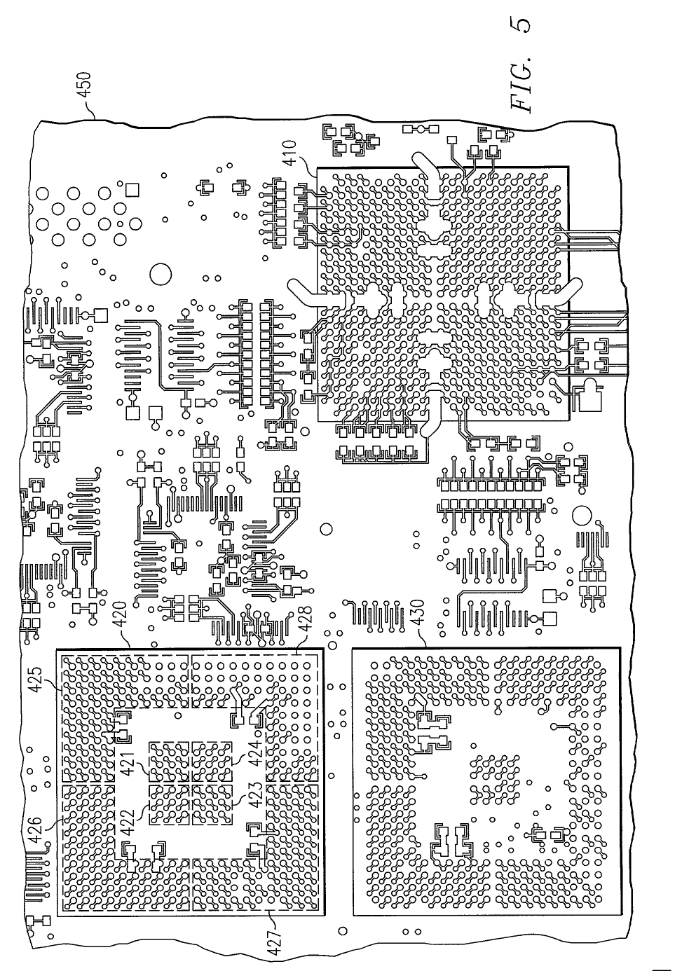

In FIG. 5, there is illustrated a printed circuit board 450 having multiple semiconductor device mount areas. Semiconductor mount area 410 is a four quadrant mount area having two channels similar to those discussed with reference to FIGS. 2 and 4. Semiconductor mount areas 420 and 430 incorporate attach pad and via arrangements embodying the principles taught by the present invention as described hereinabove but designed for semiconductor device mounts having alternative lead arrangements. For example, mount area 420 comprises four quadrants 421-424 that are placed internally to four surrounding quadrants 425-428. The attach pad and via arrangements depicted, as well as those aforedescribed, are illustrative only. It should be understood that any number of arrangements are possible and the invention is not intended to be limited to those described herein.

Although one or more embodiments of the method and apparatus of the present invention has been illustrated in the accompanying drawings and described above, it will be understood that the invention is not limited to the embodiment disclosed, but is capable of numerous rearrangements, modifications and substitutions without departing from the spirit of the invention as set forth and defined by the following claims.

What is claimed is:

1. A printed circuit board having at least one mount area on a first surface thereof capable of having a microelectronic semiconductor device coupled thereto, said mount area having a plurality of attach pads on said first surface and a plurality of vias extending from said first surface to a second surface of said printed circuit board, said printed circuit board comprising:
a plurality of collinear arrangements of vias, each of said collinear arrangements of vias including a respective first plurality of vias, each of said first plurality of vias being separated by a first distance from at least one adjacent via, said at least one adjacent via included in said first plurality of vias; and
a plurality of collinear arrangements of attach pads, each of said collinear arrangements of attach pads including a respective first plurality of attach pads, each of said first plurality of attach pads being separated a second distance from at least one adjacent attach pad, said at least one adjacent attach pad included in said first plurality of attach pads, each of said collinear arrangements of attach pads being adjacently separated by a third distance from at least one of said first plurality of collinear arrangements of said vias, at least two of said first plurality of collinear arrangements of vias being adjacently separated by a fourth distance, and at least two of said first plurality of collinear arrangements of vias being adjacently separated by a fifth distance substantially equivalent to two times the fourth distance.

2. The printed circuit board according to claim 1, wherein said first distance and said second distance are equivalent.

3. The printed circuit board according to claim 1, wherein said third distance is substantially equal to one half said fourth distance.

4. The printed circuit board according to claim 1, wherein each of said first plurality of attach pads respectively included in each of said plurality of collinear arrangements of attach pads respectively provide an electrical contact for a lead of said microelectronic semiconductor device.

5. The printed circuit board according to claim 4, wherein said microelectronic semiconductor device is a ball grid array microelectronic semiconductor device.

6. The printed circuit board according to claim 4, wherein said microelectronic semiconductor device is a fine grid ball array semiconductor device.

7. The printed circuit board according to claim 1, further comprising at least one signal trace on said first surface of said printed circuit board, a portion of said at least one signal trace passing through said mount area, said portion being adjacent to at least two of said collinear arrangements of attach pads.

8. The printed circuit board according to claim 1, further comprising at least one capacitor mounted on said second surface of said printed circuit board on an area below said mount area, said at least one capacitor being mounted between two of said collinear arrangements of vias separated by said fifth distance.

9. The printed circuit board according to claim 8, where in said capacitor is a decoupling capacitor operable to decouple power from at least one lead of said microelectronic semiconductor device.

10. A method of routing a signal trace on a printed circuit board having a mount area including a plurality of collinear arrangements of attach pads and a plurality of collinear arrangements of vias, said mount area operable to couple a microelectronic semiconductor device thereto, said method comprising the steps of:
adjacently separating each of said plurality of collinear arrangements of attach pads by a first distance;
adjacently separating a subset of said plurality of collinear arrangements of vias by a second distance;
adjacently separating at least a first and a second of said plurality of collinear arrangements of vias by a third distance; and
routing said signal trace through said mount area, said signal trace having a portion thereof adjacent to at least two of said collinear arrangements of attach pads.

11. The method according to claim 10, wherein said at least two of said collinear arrangements of attach pads are respectively adjacent to said first and second collinear arrangement of vias separated by said third distance.

12. The method according to claim 10, wherein said third distance is substantially equivalent to two times said second distance.

13. The method according to claim 10, wherein said first distance and said second distance are substantially equivalent.

14. A printed circuit board having at least one mount area for a microelectronic semiconductor device, said mount area comprising:
a first subset of vias; and
a second subset of vias being spaced from said first subset of vias by a distance greater than a common inter-via distance between adjacent vias within each subset of vias, thereby defining an area unpopulated by said vias.

15. The printed circuit board, as set forth in claim 14, wherein the unpopulated area comprises a channel operable to accommodate at least one signal trace therethrough on a first surface of the printed circuit board.

16. The printed circuit board, as set forth in claim 14, wherein the unpopulated area is operable to accommodate at least one electronic circuit element on a second surface of the printed circuit board.

17. The printed circuit board, as set forth in claim 16, wherein the electronic circuit element is a decoupling capacitor operable to decouple power from leads of the microelectronic semiconductor device.

18. The printed circuit board, as set forth in claim 14, wherein a width of the unpopulated area is at least twice the common inter-via distance.
